(19) United States
(12) Patent Application Publication
(10) Pub. No.: US 2006/0148223 A1
(43) Pub. Date: Jul. 6, 2006

(54) Wafer surface pre-treatment with hydrogen for gate oxide formation

(75) Inventor: Tae Hong Lim, Incheon (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/320,614

(22) Filed: Dec. 30, 2005

(30) Foreign Application Priority Data
Dec. 31, 2004 (KR) 10-2004-0117846

(51) Int. Cl. H01L 21/425

(52) U.S. Cl. 438/516; 438/530

(57) ABSTRACT

A method of pre-treating a wafer surface including loading the wafer into a furnace, purging the furnace to discharge oxygen gas by supplying nitrogen gas, and baking the wafer while hydrogen gas is supplied into the furnace at a defined temperature and for a defined time.

This U.S. non-provisional application claims priority under 35 U.S.C. §119 from Korean Patent Application No. 2004-117846, which was filed in the Korean Intellectual Property Office on Dec. 31, 2004, the contents of which are incorporated by reference herein in its entirety.

### BACKGROUND OF THE INVENTION

1. Field of the Invention

The present invention relates generally to wafer fabrication technology and, more particularly, to a method of pre-treating a wafer surface with hydrogen to remove oxide layers remaining on the surface before forming a gate oxide layer.

2. Description of the Related Art

In general, a typical wafer fabrication process involves several ion implantation steps, one of which is performed for adjusting a channel threshold voltage (Vt) before a gate oxide layer is formed. If ion dopants are implanted directly into the surface of a silicon substrate, crystal structures near the surface may be physically damaged by the impact of the implanted ions. Thus, the ion implantation process for Vt adjustment requires a buffer layer such as a sacrificial oxide layer. Well-known thermal oxidation techniques are used to form such a sacrificial oxide layer. Normally the sacrificial oxide layer is grown in a rapid thermal processing system and then annealed for densification.

The sacrificial oxide layer may be contaminated by ion dopants during the implantation process. Thus, the sacrificial oxide layer should be removed before the formation of the gate oxide layer after the implantation process. In a conventional method, a chemical solution containing hydrofluoric acid (HF) is often used to remove the sacrificial oxide layer from the substrate surface. After this wet etching, the substrate surface is wet-cleaned again by another chemical solution containing hydrogen peroxide (H₂O₂).

In order to obtain a desirable gate oxide layer with excellent quality and uniform thickness, the sacrificial oxide layer should be completely removed, and further, a resulting exposed surface of the silicon substrate should have good uniformity. Completely removing the sacrificial oxide layer may, however, result in over-etching that may cause damage or contamination to the substrate surface. Therefore, wet cleaning for surface treatment often follows the wet etching before the gate oxide layer is formed. Unfortunately, wet cleaning with H₂O₂ may create a native oxide layer that chemically grows on the substrate surface to a non-uniform thickness of 3˜10 Å.

### SUMMARY OF THE INVENTION

Exemplary, non-limiting embodiments of the present invention provide a method of pre-treating a wafer surface so as to effectively remove oxide layers remaining on the surface and thereby to obtain a desirable gate oxide layer with good quality and uniform thickness.

According to an exemplary embodiment of the present invention, the method comprises loading the wafer into a furnace and then purging the furnace by supplying nitrogen gas into the furnace. By purging the furnace with nitrogen gas, oxygen gas is discharged from the furnace. The method further comprises baking the wafer by supplying hydrogen gas into the furnace at a defined temperature and for a defined time. By baking the wafer with hydrogen, oxide layers remaining on the wafer surface are removed.

In the baking of the wafer, the defined temperature and the defined time may be about 900° C. and about 20 minutes, respectively. Furthermore, the hydrogen gas may be supplied into the furnace at a flow rate of about 10˜20 liters/minute.

The method may further comprise, before loading of the wafer, removing a sacrificial oxide layer from the wafer surface by using a first chemical solution containing hydrofluoric acid, and cleaning the wafer surface by using a second chemical solution containing hydrogen peroxide.

In addition, exemplary embodiments of the present invention provide a method of forming a gate oxide layer on a surface of a silicon substrate. This method comprises removing a sacrificial oxide layer from the substrate surface by using a first chemical solution containing hydrofluoric acid; cleaning the substrate surface by using a second chemical solution containing hydrogen peroxide; loading the silicon substrate into a furnace; purging the furnace by supplying nitrogen gas into the furnace to discharge oxygen gas from the furnace; baking the silicon substrate by supplying hydrogen gas into the furnace at a defined temperature and for a defined time to remove oxide layers remaining on the substrate surface; and thermally growing the gate oxide layer on the substrate surface.

It is to be understood that both the foregoing general description of the invention and the following detailed description are exemplary, but are not restrictive of the invention.

### BRIEF DESCRIPTION OF THE DRAWINGS

FIG. 1 is a flow chart of a wafer surface pre-treatment method in accordance with an exemplary embodiment of the present invention.

FIG. 2 is a schematic view of a furnace used for the wafer surface pre-treatment method shown in FIG. 1.

### DETAILED DESCRIPTION OF EXEMPLARY EMBODIMENTS OF THE INVENTION

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

It is noted that well-known structures and processes are not described or illustrated in detail to avoid obscuring the essence of the present invention.

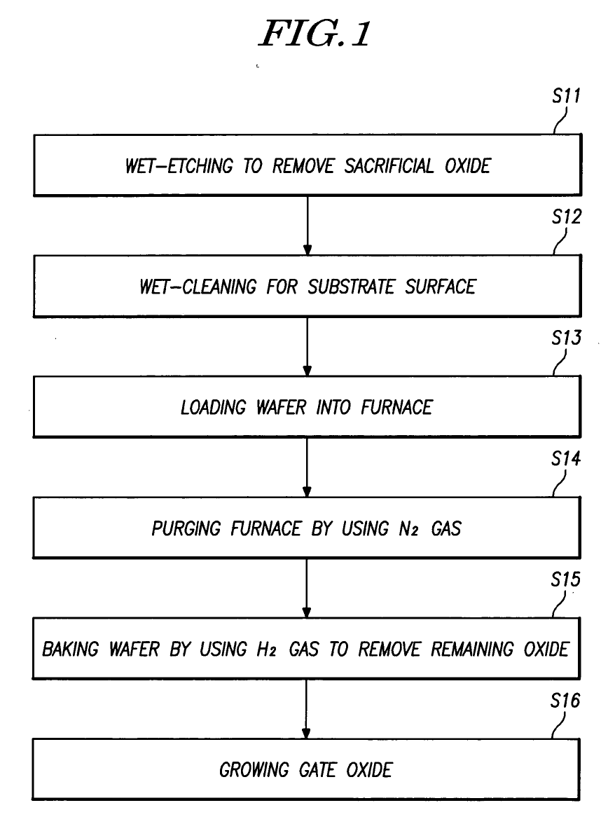

FIG. 1 is a flow chart of a wafer surface pre-treatment method in accordance with an exemplary embodiment of the present invention.

Referring to FIG. 1, the formation of a gate oxide layer on a silicon substrate requires pre-treating the top surface of the silicon substrate. At the outset, a wet-etching step (S11) is performed to remove a sacrificial oxide layer from the substrate surface. This wet-etching step may use a chemical solution containing hydrofluoric acid (HF). The substrate surface is then subjected to a wet-cleaning step (S12), which may use another chemical solution containing hydrogen peroxide (H₂O₂).

As discussed above, the wet cleaning with H₂O₂ may inherently create a native oxide layer on the substrate surface. This native oxide layer chemically grows to a non-uniform thickness of 3˜10 Å. Therefore, to completely remove remaining oxide layers including such native oxide layers, the following steps are carried out in sequence.

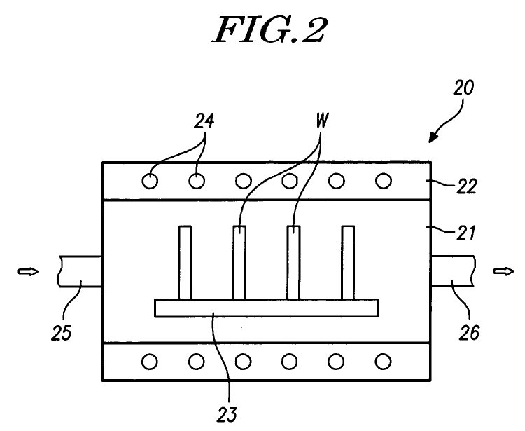

Initially the wafer is loaded into a furnace (S13). FIG. 2 illustrates, in a schematic view, the furnace 20 used for the wafer surface pre-treatment method shown in FIG. 1. Referring to FIG. 2, the furnace 20 includes a furnace tube 21 in which pre-treatment processes are performed, and a furnace body 22 surrounding the furnace tube 21. A wafer boat 23 is installed in the furnace tube 21 to support the wafers (W) mounted thereon. A heating element 24 is installed in the furnace body 22 to apply adequate heat to the furnace tube 21. In addition, the furnace tube 21 is connected at both ends to a gas supply line 25 and a gas exhaust line 26.

Returning to FIG. 1, the wafer (W) is loaded into the furnace tube 21 and mounted on the wafer boat 23 (S13). Then, in order to fully discharge oxygen gas from the furnace tube 21, the furnace 20 is purged by supplying nitrogen (N₂) gas into the furnace tube 21 through the gas supply line 25 (S14).

Thereafter, the wafer (W) is subjected to a baking step (S15) in which adequate heat is applied to the furnace tube 21 through the heating element 24 and hydrogen (H₂) gas is supplied into the furnace tube 21 through the gas supply line 25. The baking step (S15) is performed at a defined temperature, e.g., at about 900° C., and for a defined time, e.g., for about 20 minutes. The hydrogen gas may be supplied at a flow rate of about 10˜20 liters/minute.

In the baking step (S15) in a hydrogen atmosphere, oxide layers on the substrate surface may be turned into water vapor by reaction with hydrogen gas and exhausted through the gas exhaust line 26. Therefore, all the oxide layers remaining on the substrate surface are completely removed, so the surface of the wafer has good uniformity.

After the surface pre-treatment processes are finished, a gate oxide layer is thermally grown on the substrate surface (S16). Since the surface maintains good uniformity due to pre-treatment with hydrogen, the gate oxide layer can be grown with good quality and uniform thickness.

While this invention has been particularly shown and described with reference to an exemplary embodiment thereof, it will be understood by those skilled in the art that various changes in form and details may be made therein without departing from the spirit and scope of the invention as defined by the appended claims.

What is claimed is:

1. A method of pre-treating a wafer surface for a gate oxide layer, the method comprising:
loading the wafer into a furnace;
purging the furnace by supplying nitrogen gas into the furnace to discharge oxygen gas from the furnace; and
baking the wafer by supplying hydrogen gas into the furnace at a defined temperature and for a defined time to remove oxide layers remaining on the surface of the wafer.

2. The method of claim 1, wherein the baking includes baking at a defined temperature of about 900° C.

3. The method of claim 1, wherein the baking includes baking for a defined time of about 20 minutes.

4. The method of claim 1, wherein baking includes supplying the hydrogen gas into the furnace at a flow rate of about 10˜20 liters/minute

5. The method of claim 1, further comprising:
before loading the wafer, removing a sacrificial oxide layer from the surface of the wafer by using a first chemical solution containing hydrofluoric acid.

6. The method of claim 5, further comprising:
after the removing of the sacrificial oxide layer, cleaning the surface of the wafer by using a second chemical solution containing hydrogen peroxide.

7. A method of forming a gate oxide layer on a surface of a silicon substrate, the method comprising:
removing a sacrificial oxide layer from the surface of the silicon substrate by using a first chemical solution containing hydrofluoric acid;
cleaning the surface of the silicon substrate by using a second chemical solution containing hydrogen peroxide;
loading the silicon substrate into a furnace;
purging the furnace by supplying nitrogen gas into the furnace to discharge oxygen gas from the furnace;
baking the silicon substrate by supplying hydrogen gas into the furnace at a defined temperature and for a defined time to remove oxide layers remaining on the surface of the silicon substrate; and
thermally growing the gate oxide layer on the surface of the silicon substrate.

8. The method of claim 7, wherein the baking includes baking at a defined temperature of about 900° C.

9. The method of claim 7, wherein the baking includes baking for a defined time of about 20 minutes.

10. The method of claim 7, wherein the baking includes supplying the hydrogen gas into the furnace at a flow rate of about 10˜20 liters/minute.

11. An apparatus for pre-treating a wafer surface for a gate oxide layer comprising:
means for loading the wafer into a furnace;
means for purging the furnace by supplying nitrogen gas into the furnace to discharge oxygen gas from the furnace; and
means for baking the wafer by supplying hydrogen gas into the furnace at a defined temperature and for a defined time to remove oxide layers remaining on the surface of the wafer.

12. The apparatus of claim 11, wherein the means for baking includes means for baking at a defined temperature of about 900° C.

13. The apparatus of claim 11, wherein the means for baking includes means for baking for a defined time of about 20 minutes.

14. The apparatus of claim 11, wherein means for baking includes means for supplying the hydrogen gas into the furnace at a flow rate of about 10˜20 liters/minute

15. The apparatus of claim 11, further comprising:
means for removing a sacrificial oxide layer from the surface of the wafer by using a first chemical solution containing hydrofluoric acid.

16. The apparatus of claim 15, further comprising:
means for cleaning the surface of the wafer by using a second chemical solution containing hydrogen peroxide.
